(19) United States
(12) Patent Application Publication
(10) Pub. No.: US 2011/0110534 A1
(43) Pub. Date: May 12, 2011

(54) ADJUSTABLE VOICE OUTPUT BASED ON DEVICE STATUS

(75) Inventors: Aram Lindahl, Menlo Park, CA (US); Wendy Goh, San Jose, CA (US); Allen P. Haughay, Morgan Hill, CA (US); Shawn Ellis, Sunnyvale, CA (US); Benjamin Rottler, San Franciso, CA (US); Policarpo Wood, San Franisco, CA (US)

(73) Assignee: Apple Inc., Cupertino, CA (US)

(21) Appl. No.: 12/617,307

(22) Filed: Nov. 12, 2009

(51) Int. Cl. H03G 3/00

(52) U.S. Cl. 381/107

(57) ABSTRACT

This is directed to providing voice audio output to a user of an electronic device. To allow a user to immediately recognize the status of one or more processes or components of the electronic device from voice audio output, independent of the content of the voice audio output, the electronic device can adjust the voice audio output based on the status of the device. For example, the voice audio output can be adjusted to sound more or less tired based on the battery level of the device. As another example, the pitch or speed of voice audio output can change to identify the particular network or type of network to which a device is connected. The change in voice audio output can be correlated to any suitable device status, including for example using a linear or non-linear correlation.

### BACKGROUND

This is directed to adjusting attributes of an audio clip played back to describe the status of an electronic device. In particular, this is directed to adjusting the manner in which a voice sounds based on the status of the electronic device.

Many electronic devices provide a significant number of features or operations accessible to a user. The number of available features or operations may often exceed the number of inputs available using an input interface of the electronic device. To allow users to access electronic device operations that are not specifically tied to particular inputs (e.g., inputs not associated with a key sequence or button press, such as a MENU button on an iPod, available from Apple Inc.), the electronic device may provide menus with selectable options, where the options are associated with electronic device operations. For example, an electronic device may display a menu with selectable options on a display, for example in response to receiving an input associated with the menu from an input interface (e.g., a MENU button).

Because the menu is typically displayed on an electronic device display, a user may be required to look at the display to select a particular option. This may sometimes not be desirable. For example, if a user desires to conserve power (e.g., in a portable electronic device), requiring the electronic device to display a menu and move a highlight region navigated by the user to provide a selection may use up power. As another example, if a user is in a dark environment and the display does not include back lighting, the user may not be able to distinguish displayed options of the menu. As still another example, if a user is blind or visually impaired, the user may not be able to view a displayed menu.

To overcome this issue, some systems may provide audio feedback in response to detecting an input from a user or a change in battery status, as described in commonly assigned U.S. Patent Publication No. 2008/0129520, entitled “ELECTRONIC DEVICE WITH ENHANCED AUDIO FEEDBACK” (Attorney Docket No. P4250US1, which is incorporated by reference herein in its entirety. The voice audio output provided can be generated from pre-recorded audio clips, or by using a text-to-speech engine to which text strings corresponding to the audio to play back are provided. The voices used to generate the audio can provide a constant and regular output in which only the content (i.e., the voice text) changes.

### SUMMARY

This is directed to systems and methods for providing voice audio output by changing attributes of the voice to indicate the device status. In particular, this can include applying audio effects to the audio clips played back by the device to provide additional feedback regarding the device status.

In some cases, a user may wish to identify available options, content stored and available for playback, or the status of one or more device components or processes. If the electronic device includes a display, the user can look at the display and navigate through menus, if necessary, to direct the device to display the information of interest. In some cases, however, the user may wish to retrieve this information without looking at the display. In particular, a user may wish to retrieve this information in a dark environment without turning on the device display. To provide this information to the user, the electronic device can provide voice audio output for device information. For example, the electronic device can provide voice audio output for menu items or other textual content displayed by the device, graphical content displayed by the device, or any other suitable content.

In some cases, the electronic device can provide voice audio output related to the status of one or more device operations, components or processes. Such operations, components or processes can include, for example, power-related status information, network-related status information, storage or memory-related status information, or any other information. Providing this information via voice audio output, however, can require the device to play back an additional audio clip (e.g., in addition to voice audio output identifying menu items or content being played back). To provide the user with the device status information without requiring a second voice audio output, the electronic device can modify the voice used for the voice audio output of the audio clip used to identify the menu items or media content. In particular, the electronic device can modify the language, accent, pitch, speed, timbre, or any other attribute of the voice based on the device status.

By modifying the voice used for the voice audio output, a user can identify two types of unrelated information from a single voice audio output. In particular, the user can identify first information from the content of the voice audio output, and second information from the modification of the audio clip. The amount by which the voice audio output is changed can be related to the status of the device (e.g., the amount by which a status value differs from a threshold).

### BRIEF DESCRIPTION OF THE DRAWINGS

The above and other features of the present invention, its nature and various advantages will be more apparent upon consideration of the following detailed description, taken in conjunction with the accompanying drawings in which:

FIG. 1 is a schematic view of a electronic device in accordance with one embodiment of the invention;

FIG. 2 is a schematic view of an illustrative display screen having content for which voice audio output may be available in accordance with one embodiment of the invention;

FIG. 3 is a schematic view of an illustrative electronic device settings display in accordance with one embodiment of the invention;

FIG. 4 is a schematic view of an illustrative data structure for associating inputs with particular voice audio output in accordance with one embodiment of the invention;

FIG. 5 is a schematic view of an illustrative display for associating the device status with voice attributes in accordance with one embodiment of the invention;

FIG. 6 is a flowchart of an illustrative process for adjusting attributes of a voice used for voice audio output in accordance with one embodiment of the invention;

FIG. 7 is a flowchart of an illustrative process for adjusting voice attributes for voice audio output whose content is unrelated to the change of voice attribute in accordance with one embodiment of the invention; and

FIG. 8 is a flowchart of an illustrative process for playing back adjusted voice audio output in accordance with one embodiment of the invention.

### DETAILED DESCRIPTION

An electronic device is operative to provide voice audio output in which the attributes of the voice used to provide the feedback can change based on one or more system properties.

The electronic device may include a processor and a display. The electronic device may display any suitable information to the user. For example, a display may include a title bar, a menu with selectable options, an information region for displaying information related to one or more options, information identifying media or files available for selection, or any other suitable information. As the user selects options on the display, the electronic device may change the displayed content to reflect the user's selection.

The display can include any suitable type of content, including for example information regarding available electronic device operations, status information regarding one or more device components, identifying information for content stored by the device (e.g., locally stored media items), content accessed from a remote source (e.g., displayed web pages), or any other suitable content. In some embodiments, the electronic device can provide voice audio output describing one or more portions of the displayed content. For example, the electronic device can provide voice audio output describing available selectable options. As another example, the electronic device can provide voice audio output describing the difference in displayed content as the user navigates between electronic device screens.

In some embodiments, a user may wish to receive audio feedback or output regarding the status of one or more electronic device components. For example, a user may wish to receive feedback regarding the current power status of the device, the network availability, space available in storage, available processing resources, or the status of any other suitable device component. The electronic device can provide voice audio output indicative of the status of these components using any suitable approach. For example, the electronic device can play back audio clips describing the status of the components (e.g., “30% battery remaining)”.

In some cases, however, the electronic device can provide device status information using a voice clip associated with text that does not include the status information. This can allow the electronic device to provide voice audio output having two distinct messages to a user using a single voice clip. In one implementation, the content of the voice clip can be associated information displayed by the device (e.g., a voice clip related to a displayed option), while the characteristics of the voice used to produce the voice clip can be associated with device status information. For example, the voice used in the voice clip can be more or less tired (or chipper) based on the amount of power remaining in the device battery. In particular, the voice can become slower and lower-pitches when the device power falls below a threshold.

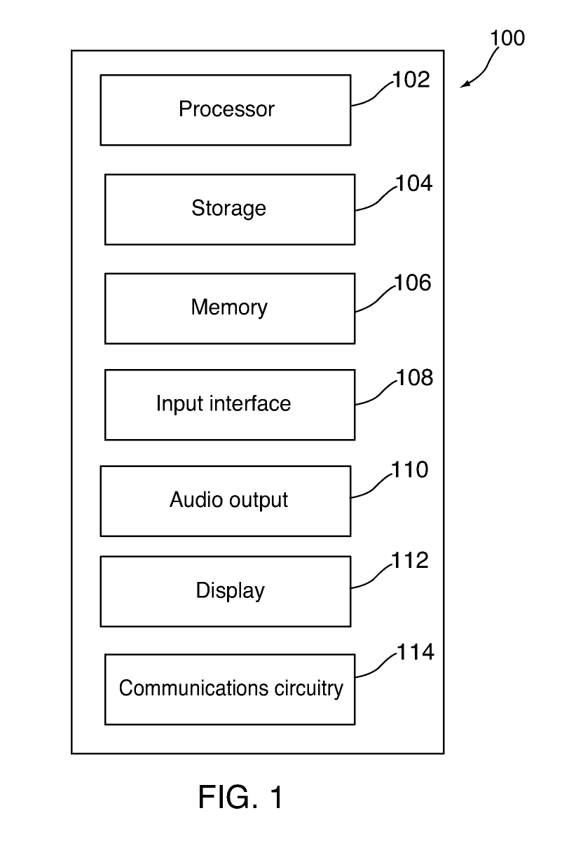

FIG. 1 is a schematic view of a electronic device in accordance with one embodiment of the invention. Electronic device 100 may include processor 102, storage 104, memory 106, input interface 108, audio output 110, display 112, and communications circuitry 114. In some embodiments, one or more of electronic device components 100 may be combined or omitted (e.g., combine storage 104 and memory 106). In some embodiments, electronic device 100 may include other components not combined or included in those shown in FIG. 1 (e.g., a power supply or a bus), or several instances of the components shown in FIG. 1. For the sake of simplicity, only one of each of the components is shown in FIG. 1.

Processor 102 may include any processing circuitry operative to control the operations and performance of electronic device 100. For example, processor 102 may be used to run operating system applications, firmware applications, media playback applications, media editing applications, or any other application. In some embodiments, a processor may drive a display and process inputs received from a user interface.

Storage 104 may include, for example, one or more storage mediums including a hard-drive, solid state drive, flash memory, permanent memory such as ROM, any other suitable type of storage component, or any combination thereof. Storage 104 may store, for example, media data (e.g., music and video files), application data (e.g., for implementing functions on device 100), firmware, user preference information data (e.g., media playback preferences), authentication information (e.g. libraries of data associated with authorized users), lifestyle information data (e.g., food preferences), exercise information data (e.g., information obtained by exercise monitoring equipment), transaction information data (e.g., information such as credit card information), wireless connection information data (e.g., information that may enable electronic device 100 to establish a wireless connection), subscription information data (e.g., information that keeps track of podcasts or television shows or other media a user subscribes to), contact information data (e.g., telephone numbers and email addresses), calendar information data, and any other suitable data or any combination thereof.

Memory 106 can include cache memory, semi-permanent memory such as RAM, and/or one or more different types of memory used for temporarily storing data. In some embodiments, memory 106 can also be used for storing data used to operate electronic device applications, or any other type of data that may be stored in storage 104. In some embodiments, memory 106 and storage 104 may be combined as a single storage medium.

Input interface 108 may provide inputs to input/output circuitry of the electronic device. Input interface 108 may include any suitable input interface, such as for example, a button, keypad, dial, a click wheel, or a touch screen. In some embodiments, electronic device 100 may include a capacitive sensing mechanism, or a multi-touch capacitive sensing mechanism. Some sensing mechanisms are described in commonly owned U.S. patent application Ser. No. 10/902,964, filed Jul. 10, 2004, entitled “Gestures for Touch Sensitive Input Device,” and U.S. patent application Ser. No. 11/028,590, filed Jan. 18, 2005, entitled “Mode-Based Graphical User Interfaces for Touch Sensitive Input Device,” both of which are incorporated herein in their entirety.

Audio output 110 may include one or more speakers (e.g., mono or stereo speakers) built into electronic device 100, or an audio connector (e.g., an audio jack or an appropriate Bluetooth connection) operative to be coupled to an audio output mechanism. For example, audio output 110 may be operative to provide audio data using a wired or wireless connection to a headset, headphones or earbuds.

Display 112 may include display circuitry (e.g., a screen or projection system) for providing a display visible to the user. For example, display 112 may include a screen (e.g., an LCD screen) that is incorporated in electronic device 100. As another example, display 112 may include a movable display or a projecting system for providing a display of content on a surface remote from electronic device 100 (e.g., a video projector). In some embodiments, display 112 can include a coder/decoder (Codec) to convert digital media data into analog signals. For example, display 112 (or other appropriate circuitry within electronic device 100) may include video Codecs, audio Codecs, or any other suitable type of Codec.

Display 112 also can include display driver circuitry, circuitry for driving display drivers, or both. Display 112 may be operative to display content (e.g., media playback information, application screens for applications implemented on the electronic device, information regarding ongoing communications operations, information regarding incoming communications requests, or device operation screens) under the direction of processor 102.

Communications circuitry 114 may be operative to communicate with other devices or with one or more servers using any suitable communications protocol. Electronic device 100 may include one more instances of communications circuitry for simultaneously performing several communications operations using different communications networks. For example, communications circuitry may support Wi-Fi (e.g., a 802.11 protocol), Ethernet, Bluetooth™ (which is a trademark owned by Bluetooth Sig, Inc.), radio frequency systems, cellular networks (e.g., GSM, AMPS, GPRS, CDMA, EV-DO, EDGE, 3GSM, DECT, IS-136/TDMA, iDen, LTE or any other suitable cellular network or protocol), infrared, TCP/IP (e.g., any of the protocols used in each of the TCP/IP layers), HTTP, FTP, RTP, RTSP, SSH, Voice over IP (VOIP), any other communications protocol, or any combination thereof. In some embodiments, communications circuitry 114 may include one or more communications ports operative to provide a wired communications link between electronic device 100 and a host device. For example, a portable electronic device may include one or more connectors (e.g., 30 pin connectors or USB connectors) operative to receive a cable coupling the portable electronic device to a host computer. Using software on the host computer (e.g. iTunes available from Apple Inc.), the portable electronic device may communicate with the host computer.

In some embodiments, electronic device 100 may include a bus operative to provide a data transfer path for transferring data to, from, or between control processor 102, storage 104, memory 106, input interface 108, audio output 110, display 112, communications circuitry 114, and any other component included in the electronic device.

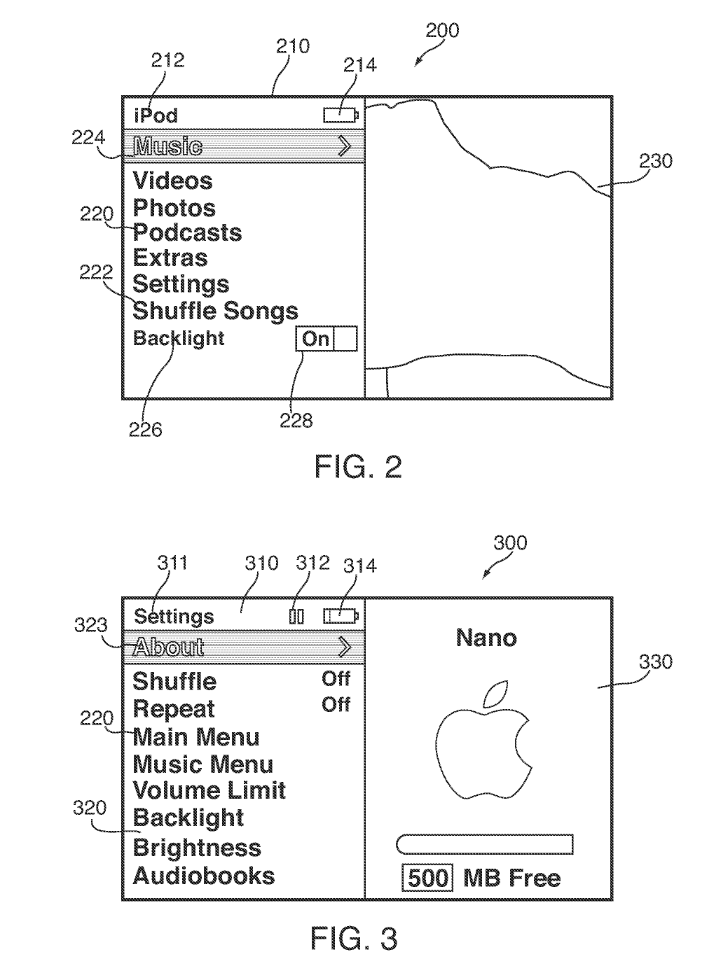

The electronic device may provide voice audio output for any suitable displayed content, including for example menu options or content available for playback to a user (e.g., voice audio output for metadata associated with media, such as an artist name, media title, or album). FIG. 2 is a schematic view of an illustrative display screen having content for which voice audio output may be available in accordance with one embodiment of the invention. Display 200 may include several areas on which content is displayed as a combination of one or more display elements. For example, display 200 may include title bar 210, menu 220 and additional information 230. Title bar 210 may include title 212 indicating the mode or application in use by the electronic device. For example, title 212 may include iPod (e.g., the top most title when no application has been selected), Music, Videos, Photos, Podcasts, Extras, and Settings. Other titles may be available, for example when an accessory device is coupled to the electronic device (e.g., a radio accessory or workout accessory). Title bar 210 may also include any other suitable information, including for example battery indicator 214.

Menu 220 may include several selectable options 222, including for example options for selecting a mode or application, or options associated with a particular selected mode or application. A user may select an option from menu 220 by navigating highlight region 224 over an option. The user may provide a selection instruction (e.g., by pressing a button or providing any other suitable input) while the highlight region is over a particular option to select the particular option. Additional information 230 may include any suitable information, including for example information associated with the mode or application identified by title 212, one or more displayed options 222, the particular option identified by highlight region 224, or any other suitable information.

The electronic device may generate display 200, or any other display using any suitable approach. In some embodiments, a Model-View-Controller (MVC) architecture or design may be used. The electronic device can provide voice audio output for one or more displayed elements (e.g., displayed icons, menu items, options, or glyphs) using any suitable approach. To tie the voice output to displayed elements, the MVC architecture can be modified to include voice output related variables. In some embodiments, a voice output can instead or in addition be provided independent of displayed content. The voice output architecture can then independent of the display architecture.

The electronic device can provide voice audio output for displayed elements (or for other device content or status information) using any suitable approach. In some embodiments, the electronic device can include a speech scheduler for defining and maintaining a queue of items for which to provide voice audio output. The speech scheduler can include any hardware, firmware, and/or software (e.g., an application or process operated by electronic device circuitry) of the electronic device for controlling the manner in which voice audio outputs are provided. The speech scheduler can be updated as the user navigates through menus, or as the device status changes. The electronic device may provide a voice audio output signal for any suitable combination of displayed elements, including for example only one menu item (e.g., the menu item identified by a highlight region), several menu items (e.g., all menu items that come after the highlighted menu item), or all menu items.

In the example of FIG. 2, the speech scheduler can direct the electronic device to provide an audio output signal corresponding to any of the items of title bar 210, menu 220 and additional information 230. For example, the electronic device can provide voice audio output for the text items of the display regions (e.g., the items of option 222). As another example, the electronic device can provide voice audio output associated with symbols in display 200 (e.g., the level of battery indicator 214), or a description of the album art displayed in additional information region 230.

The particular information, and corresponding voice audio output can be provided for any suitable electronic device display. In particular, the electronic device can provide voice audio output for settings and status information of the electronic device. FIG. 3 is a schematic view of an illustrative electronic device settings display in accordance with one embodiment of the invention. Display 300 can include title bar 310 identifying the display as a “Settings” display, options region 320, and additional information region 330. Title bar 310 can include, in addition to title 311, play/pause icon 312 indicating the current status of the device, and battery level indicator 314. Options region 320 can include listing 322 of selectable options. In response to selecting an option, the electronic device can provide new display (e.g., new regions 310, 320 and 330), or can instead or in addition provide information to the user in additional information region 330. For example, in response to highlighting about option 323, the electronic device can initially display information describing the type of device and the amount of storage remaining in additional information region 330. In response to highlighting about option 323, the electronic device can instead or in addition provide a new display detailing the usage of the device, current firmware or software, serial number, component status, or any other information for the device.

The electronic device can provide voice audio output for any of the settings information shown in display 300. For example, the electronic device can provide voice audio output related to text elements displayed in one of regions 320 and 330. In particular, the electronic device can provide voice audio output related to a currently highlighted item. In some cases, the electronic device can provide voice audio output for some key items in display 300, such as the status of particular device components or device processes that are important to the user. For example, the electronic device can provide voice audio output for the current status of the power supply (e.g., battery remaining or connected to external power source), rate of power consumption (e.g., amount of power remaining if the currently running processes continue), current volume level (e.g., as dB or as a percentage of total volume so that the user can have a reference for the current volume level), storage remaining, processing power used (e.g., as a percentage of available power), communications network statistics (e.g., strength of signal, current wireless network (e.g., identity of a WiFi network or number of available network), type of network (e.g., Edge, 3G, 4G or 802.11), newly received messages (e.g., email or text messages), or any other device status information that may be of interest to the user.

Because a user may wish to know the status of a particular device operation or process without needing to navigate to a corresponding status display, the electronic device can provide voice audio output for device status information from other displays. For example, the electronic device can include a particular input for playing back an audio clip describing the status of one or more device operations or systems. The device can associate different combinations of device status voice audio outputs with individual inputs. For example, each device status can be associated with a particular input. As another example, sets of device status (e.g., current battery level, current rate of battery use, and time left before battery runs out) can be associated with a single input. The input can be received using any suitable approach. For example, the input can include a particular sequence of button presses on one or more buttons of the device. As another example, the input can include a particular sequence of touch gestures provided on a touch-sensitive input interface. As still another example, the input can include a voice command received by a microphone of the device. Finally, an input can include any suitable combination of these or other types of inputs.

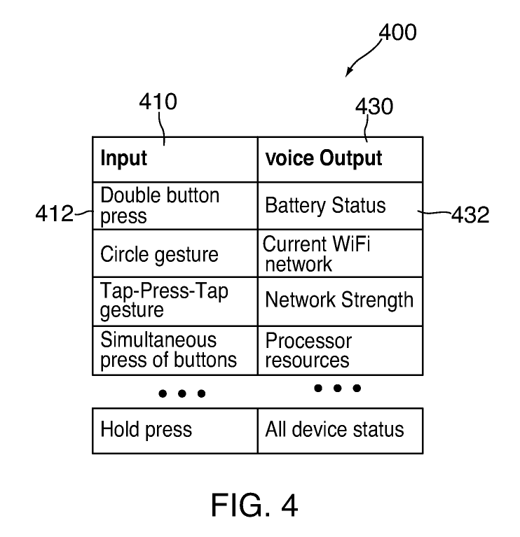

FIG. 4 is a schematic view of an illustrative data structure for associating inputs with particular voice audio output in accordance with one embodiment of the invention. Data structure 400 can include column 410 of inputs and column 430 of voice audio outputs. The input identified in each row can correspond to a voice audio output in the same row. For example, a double button press (e.g., input 412) can correspond to a battery status voice clip (e.g., voice audio output 432). Data structure 400 can include any suitable combination of voice audio outputs associated with a particular input, including for example all device status voice audio outputs.

The electronic device can provide voice audio output using any suitable voice. For example, the electronic device can apply a particular voice or voice type (e.g., defined by a voice print) to text strings to generate an audio clip for voice audio output. As another example, the electronic device can play back audio clip recordings of a person speaking text strings. To provide a consistent experience, a single voice can be used for all of the text strings (e.g., strings describing menu options and strings identifying media items available for playback). In some embodiments, the electronic device can instead or in addition change the particular voice used based on the context of the voice audio output. For example, the electronic device could use different voices for describing menu options and for identifying content available for playback. The user could then immediately tell, from the first sounds made by the voice, the type of information being provided by the voice audio output. This may allow the user to fast-forward through the voice audio output, or stop the voice audio output, so as to only hear voice audio output for information of interest to the user.

In all of these approaches, however, a user may need to listen to the actual voice audio output providing the device status information. If the user wishes to both hear identifying information for a currently played back media item, as well as current status information, the user may need to play back two distinct voice audio outputs, which can lengthen the amount of time that a media item is not played back. In some embodiments, the electronic device can instead provide both the content information and the device status information using a single voice audio output. In particular, the electronic device can play back an audio clip such that the content of the audio clip provides the content information, and the attributes or characteristics of the voice used for the audio clip provides the device status information.

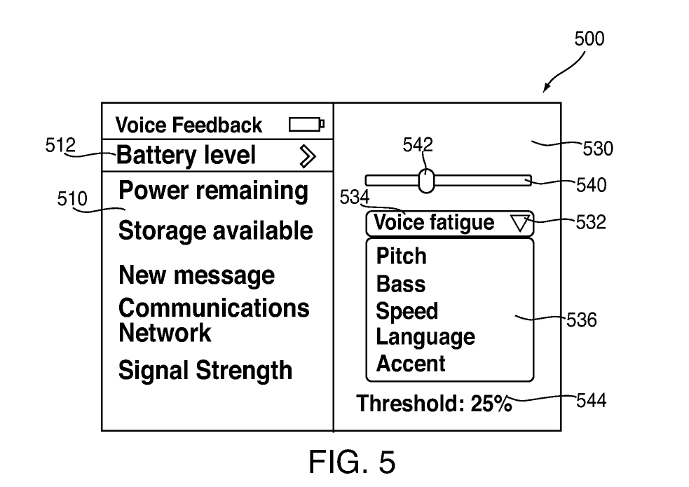

The electronic device can modify the attributes of the voice providing the voice audio output using any suitable approach. In some embodiments, the electronic device can modify the pitch, timbre, octave, scale, sharpness, volume, rhythm, speed, accent, language, sex of voice, or any other feature of the voice. In some embodiments, the electronic device can instead or in addition add or remove particular sounds from the voice audio output (e.g., add a bass line or breathing sounds, or remove a particular frequency range from the audio). In other embodiments, the electronic device can generate new audio clips for the voice audio output using a text to speech engine in which the particular voice print or voice signature used to generate the audio clip is selected based on the device status. In one implementation, the electronic device can modify the voice so that it appears to be more or less tired (e.g., more chipper, or slower and with breathing sounds). For example, the voice can sound less tired when the electronic device battery level is higher, and more tired when the electronic device battery level is lower. The electronic device can associate voice attributes with particular device status levels using any suitable approach. FIG. 5 is a schematic view of an illustrative display for associating the device status with voice attributes in accordance with one embodiment of the invention. Display 500 can include listing 510 of device status options with which one or more voice attributes can be associated. Listing 510 can include any suitable device status options, including for example battery level, power remaining, storage available, new message, communications network, and signal strength options. The user can select any of the options to associate a particular voice effect with the device status, including for example by selecting the option using highlight region 512.

In response to detecting that a particular option has been selected or highlighted, the electronic device can display options for modifying a voice used in voice audio output in additional information region 530. Additional information region 530 can include menu 532 from which a user can select a particular voice attribute 534 from the available attributes 536. The available attributes 536 shown in the menu can include any suitable attributes, and in some cases a user may scroll the menu to access other attributes. In some embodiments, the electronic device can provide the user with one or more curves or values defining the voice signature of the voice used for the voice audio output so that the user can directly modify the curves or values (e.g., the voice is defined as a particular sound wave that the user can transform). Once the user has selected the particular voice attribute to change, the user can change the value of the attribute (e.g., using slider 542 on bar 540).

The electronic device can adjust the attribute value based on the value of the corresponding device status using any suitable approach. In some embodiments, the electronic device can adjust the voice attribute to a new level or value (e.g., set by the slider) once the device status reaches a threshold or satisfies a condition (e.g., received new urgent email). As another example, the electronic device can define a correlation between the amount by which to adjust the voice attribute and the device status. For example, if the device status is optimal or near optimal (e.g., a full battery or strong WiFi signal), the electronic device can minimally or not modify the voice attribute. If the device status is far from optimal, however (e.g., low battery or weak WiFi signal), the electronic device can modify the voice attribute by a larger amount (e.g., the maximum amount defined by the slider). The correlation between the device status and modification of the voice attribute can be linear or non-linear (e.g., more pronounced as the device status reaches a threshold). In some cases, the user can define the correlation (e.g., by adjusting points on a curve).

The electronic device can determine which voice attributes to change for a particular voice audio output using any suitable approach. For example, the electronic device can constantly monitor the device status, and when a particular status value reaches a threshold, the voice audio output can be altered to reflect the particular status value. This can prevent the electronic device from modifying several voice attributes simultaneously, and preventing the user from understanding either the content of the voice audio output, or detecting the particular device status values related to the modified attributes (e.g., so that the user does not need to identify and distinguish changes in pitch, tempo and accent simultaneously). The user can define the particular threshold using any suitable approach. In some embodiments, the user can define the threshold using option 544. The threshold value can be entered using any suitable approach, including for example by directly entering a value (e.g., a number or percentage) by sliding a slider across a bar, or any other approach.

In some embodiments, the user can define one or more device status values to monitor. The electronic device can then adjust the voice used for voice audio output only when the monitored device status changes. The user can define the particular one or more status values to monitor using any suitable approach, including for example by enabling or disabling monitoring of particular device status options (e.g., in display 500). In some embodiments, the electronic device can automatically select one or more default device status values to monitor, including for example the strength of a received wireless signal or the battery remaining for the user.

The electronic device can modify one or more attributes of a voice output based on any suitable condition that the device can detect. As discussed in portions of the description above, the condition can include a device status, such as a battery level, storage availability, or any other general system status. In some embodiments, however, the condition can be determined from the output of one or more sensors of the device. For example, the electronic device can modify a voice output based on the output of an ambient light sensor (e.g., use a softer voice in darker environments). In some embodiments, the condition can include a characteristic of the current location of the electronic device. For example, the voice output can vary based on the temperature of the user's environment, or on the location of the device. The temperature can be identified using any suitable approach, including for example from a thermometer or other sensor detecting temperature, or by consulting a weather or temperature service based on a determined current location of a device. The electronic device can determine its current location using any suitable approach, including for example using positioning circuitry (e.g., GPS circuitry, cell tower triangulation, or other such approaches). In such an implementation, the attributes of a voice output can match an accent or dialect spoken in the current location of the device (e.g., use a southern accent if the device is in Georgia, but a Boston accent if the device is in New England). In some embodiments, the condition can instead or in addition include the current time of day. For example, the voice output can be louder during day hours, but softer at night. As another example, the voice output can be more relaxing at night.

In some embodiments, the condition can instead or in addition include the usage of the device. For example, the voice output can sound more tired or exasperated if the usage of the device is heavy, but more chirpy if the device usage is light. In some embodiments, the condition can instead or in addition include the number of detected devices in the same communications network as the device, or in communication with the electronic device. For example, a voice output can change to indicate to the user that many devices are available with which the user can share content, or to indicate that there may be network congestion due to the large number of devices.

In some embodiments, the condition can instead or in addition include an activity of the device. For example, the voice output can vary based on the application or type of application in use by the user of the device. As another example, the voice output can vary based on the type of content played back or accessed (e.g., different voice output for music than for movie playback). As another example, the voice output can vary based on the repetition of an activity (e.g., the voice output can sound exasperated or tired when the user has been playing a game over a long period of time, for example during a work day).

In some embodiments, the user can instead or in addition define one or more changes to the default voice output. For example, the user can select a setting adjusting the voice output for all voice output, independent of device status or other conditions. In some embodiments, one or more combinations of conditions can instead or in addition be associated with particular modifications of a voice output.

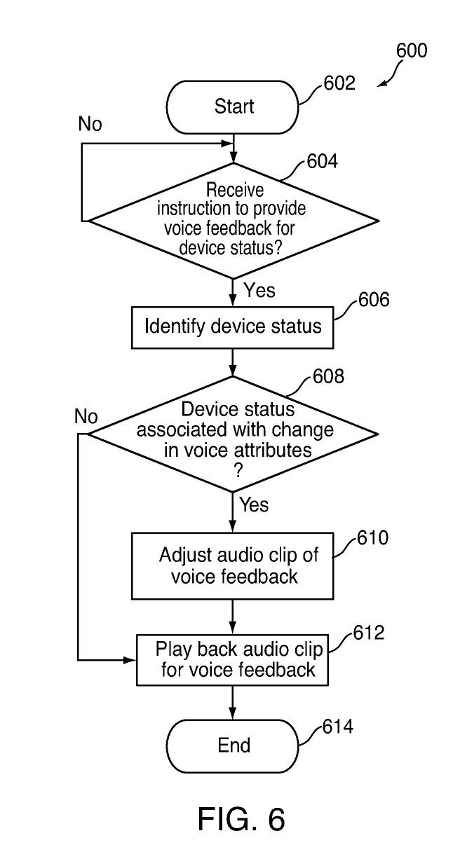

The following flowcharts describe illustrative processes used to modify attributes of voice audio output in accordance with embodiments of the invention. FIG. 6 is a flowchart of an illustrative process for adjusting attributes of a voice used for voice audio output in accordance with one embodiment of the invention. Process 600 can begin at step 602. At step 604, the electronic device can determine whether an instruction to provide voice audio output for a particular device status was received. For example, the electronic device can determine whether an input was received using an input interface. As another example, the electronic device can determine whether a timer has reached a timeout at which voice audio output is to provided. As still another example, the electronic device can determine whether the status of one or more device components or processes has reached a state for which voice audio output is to be played back. If the electronic device determines that no instruction was received for providing voice audio output, process 600 can return to step 604 and continue to monitor for an instruction to provide voice audio output.

If, at step 604, the electronic device instead determines that an instruction to provide voice audio output was received, process 600 can move to step 606. At step 606, the electronic device can identify the current status of one or more device components or processes. For example, the electronic device can determine the current status of the power supply, communications circuitry, and storage. As another example, the electronic device can determine whether a particular message or notification has been received using a particular application (e.g., push notifications, text messages, or email messages). At step 608, the electronic device can determine whether the device status is associated with a change in voice attributes. For example, the electronic device can determine whether the identified device status is associated with a change in voice attributes. For example, the electronic device can determine whether the identified device status has reached a threshold associated with changing the manner in which a voice sounds. If the electronic device determines that the identified device status is not associated with a change in voice attributes, process 600 can move to step 612, described below.

If, at step 608, the electronic device instead determines that the device status is associated with a change in voice attributes, process 600 can move to step 610. At step 610, the electronic device can adjust the audio clip of the voice audio output. For example, the electronic device can adjust an audio clip describing the device status. The audio clip can be adjusted using any suitable approach, including for example by changing the pitch, tempo, language, accent, sex, or any other attribute of the audio clip. In some embodiments, one or more sounds can be inserted in the clip (e.g., add a bass line). Process 600 can then move to step 612. At step 612, the electronic device can play back the audio clip to provide the voice audio output. The audio clip can be an original audio clip or an adjusted audio clip (e.g., following step 610). Process 600 can then end at step 614.

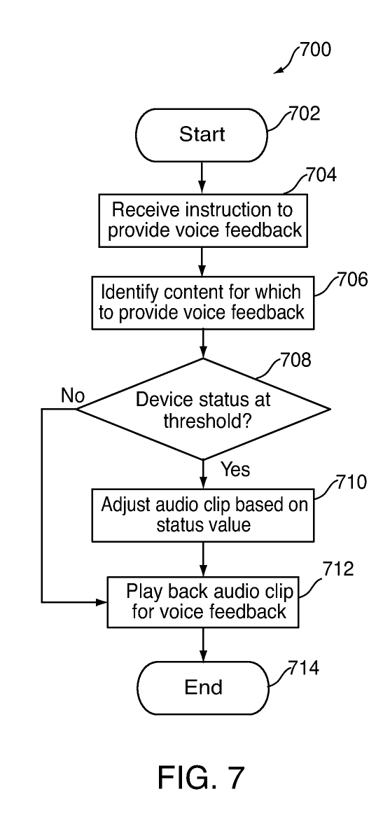

FIG. 7 is a flowchart of an illustrative process for adjusting voice attributes for voice audio output whose content is unrelated to the change of voice attribute in accordance with one embodiment of the invention. Process 700 can begin at step 702. At step 704, the electronic device can determine that voice audio output should be provided. For example, the electronic device can receive an input instructing the device to play back an audio clip serving as voice audio output. As another example, the electronic device can receive an instruction using any of the approaches described above in connection with process 600 (FIG. 6). At step 706, the electronic device can identify content for which to provide voice audio output. For example, the electronic device can identify a particular menu item for which to provide voice audio output. The particular content can include any suitable content, and in some cases content other than the current status of the device.

At step 708, the electronic device can determine whether the device status has reached a threshold. For example, the electronic device can determine whether the battery level is less than a minimum threshold. As another example, the electronic device can determine whether the strength of a communications signal is less than a minimum threshold. As still another example, the electronic device can determine whether a new message was received (e.g., an email message having a high priority, or an email message from a particular user). If the electronic device determines that the device status has not reached the threshold, process 700 can move to step 712, described in more detail below.

If the electronic device instead determines, at step 708, that the device status has reaches the threshold, process 700 can move to step 710. At step 710, the electronic device can adjust the audio clip based on the status value. In particular, the electronic device can adjust the audio of an audio clip based on the status of the device, where the actual content of the audio clip is not related to the device status. The audio can be modified using any suitable approach, including for example by modifying the pitch, speed, language, accent, sex, or any other attribute of the voice audio output. Because the content is not related to the device status, the modified voice audio output can provide the user with information related to both the audio clip content and to the device status (based on the modification of the voice audio output). Process 700 can then move to step 712. At step 712, the electronic device can play back the audio clip to provide the voice audio output. The audio clip can be an original audio clip or an adjusted audio clip (e.g., following step 710). Process 700 can then end at step 714.

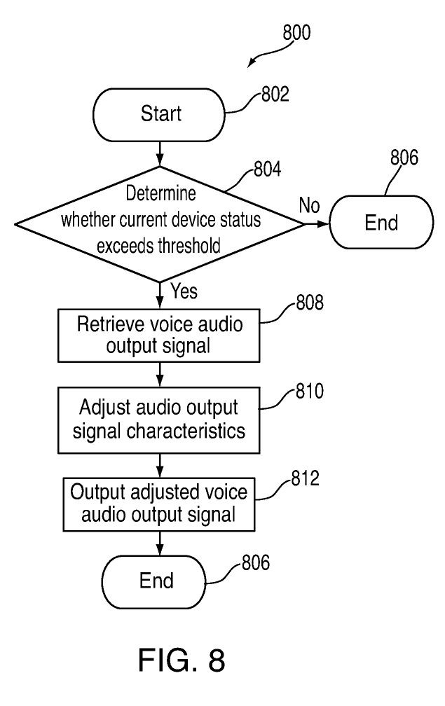

FIG. 8 is a flowchart of an illustrative process for playing back adjusted voice audio output in accordance with one embodiment of the invention. Process 800 can begin at step 802. At step 804, the electronic device can determine whether the current status of an electronic device component exceeds a threshold. For example, the electronic device can first determine the current status of the power supply, communications circuitry, and storage, and compare the status with a threshold value. As another example, the electronic device can determine whether a particular message or notification has been received using a particular application (e.g., push notifications, text messages, or email messages). If the electronic device determines that the identified device status is not associated with a change in voice attributes, process 800 can move to step 806 and end.

If, at step 804, the electronic device instead determines that the current status of the electronic device exceeds a threshold, process 800 can move to step 808. At step 808, the electronic device can retrieve a voice audio output signal to output. For example, the electronic device can retrieve from storage a voice audio output signal having content related to the determined current status. As another example, the electronic device can retrieve a voice audio output signal having content unrelated to the device status, but related to an element displayed by the device. At step 810, the electronic device can adjust the audio output signal characteristics of the retrieved audio output signal. For example, the electronic device can adjust an audio output signal describing the device status. The audio output signal can be adjusted using any suitable approach, including for example by changing the pitch, tempo, language, accent, sex, or any other attribute of the audio output signal. In some embodiments, one or more sounds can be inserted in the signal (e.g., add a bass line). Process 800 can then move to step 812. At step 812, the electronic device can output the audio output signal to provide the voice audio output. For example, the electronic device can direct an audio output to output the signal. Process 800 can then end at step 806.

Although many of the embodiments of the present invention are described herein with respect to personal computing devices, it should be understood that the present invention is not limited to personal computing applications, but is generally applicable to other applications.

Embodiments of the invention are preferably implemented by software, but can also be implemented in hardware or a combination of hardware and software. Embodiments of the invention can also be embodied as computer readable code on a computer readable medium. The computer readable medium is any data storage device that can store data which can thereafter be read by a computer system. Examples of the computer readable medium include read-only memory, random-access memory, CD-ROMs, DVDs, magnetic tape, and optical data storage devices. The computer readable medium can also be distributed over network-coupled computer systems so that the computer readable code is stored and executed in a distributed fashion.

Insubstantial changes from the claimed subject matter as viewed by a person with ordinary skill in the art, now known or later devised, are expressly contemplated as being equivalently within the scope of the claims. Therefore, obvious substitutions now or later known to one with ordinary skill in the art are defined to be within the scope of the defined elements.

The above described embodiments of the invention are presented for purposes of illustration and not of limitation.

What is claimed is:

1. A method for providing a voice audio output signal to a user of an electronic device, comprising:
determining that a current status of an electronic device exceeds a threshold;
retrieving a voice audio output signal to output;
adjusting a playback attribute of the audio output signal in response to determining; and
outputting the adjusted voice audio output signal.

2. The method of claim 1, further comprising:
receiving an instruction to provide the voice audio output signal for the current status of the electronic device.

3. The method of claim 1, wherein:
determining further comprises monitoring the status of at least one electronic device component.

4. The method of claim 3, wherein the electronic device component comprises at least one of:
a battery;
communications circuitry;
a processor; and
storage.

5. The method of claim 1, further comprising:
selecting one of a plurality of voice signatures in response to determining;
applying a text to speech engine to a text string using the selected one of the plurality of voice signatures to generate the adjusted voice audio output signal; and
outputting the adjusted voice audio output signal.

6. The method of claim 1, wherein adjusting further comprises adjusting at least one of the:
pitch;
timbre;
octave;
sharpness
scale;
rhythm;
volume;
speed;
language; and
accent.

7. The method of claim 1, wherein adjusting further comprises:
incorporating at least one additional sound in the voice audio output signal.

8. The method of claim 1, wherein adjusting further comprises:
removing at least one sound in the voice audio output signal.

9. An electronic device for providing adjusted voice audio output to a user, comprising a processor and audio output circuitry, the processor operative to:
determine that the status of an electronic device operation meets a condition;
identify voice audio output to provide, wherein the content of the voice audio output is unrelated to the status of the electronic device operation;
adjust the voice audio output based on the status of the electronic device operation; and
direct the audio output circuitry to play back the adjusted voice audio output.

10. The electronic device of claim 9, wherein the processor is further operative to:
incorporate at least one additional sound to the voice audio output.

11. The electronic device of claim 10, wherein the processor is further operative to:
incorporate fatigue sounds to the voice audio output.

12. The electronic device of claim 9, wherein the processor is further operative to:
remove at least one sound from the voice audio output.

13. The electronic device of claim 9, wherein the processor is further operative to:
receive an instruction to play back voice audio output, wherein the content of the voice audio output is related to text displayed by the device.

14. The electronic device of claim 9, wherein the condition of the electronic device operation comprises at least one of:
receiving email messages;
receiving text messages;
receiving a telephone call;
receiving a push notification; and
connecting to a type of communications network.

15. A method for playing back audio clips associated with voice audio output, comprising:
receiving an instruction to play back an audio clip as voice audio output, wherein the content of the audio clip relates to a displayed menu item;
detecting that the status of the electronic device satisfies a condition;
adjusting the audio clip based on the detected status of the electronic device; and
playing back the adjusted audio clip to provide voice audio output.

16. The method of claim 15, further comprising:
retrieving a correlation between the status of the device and the adjustment of the audio clip.

17. The method of claim 16, wherein:
the correlation comprises at least one of a linear correlation and a non-linear correlation.

18. The method of claim 17, further comprising:
displaying the correlation to the user; and
receiving a user input modifying the correlation.

19. A computer readable media for providing a voice audio output signal to a user of an electronic device, the computer readable media comprising computer program logic recorded thereon for:
determining that a current status of an electronic device exceeds a threshold;
retrieving a voice audio output signal to output;
adjusting a playback attribute of the audio output signal in response to determining; and
outputting the adjusted voice audio output signal.

20. The computer readable media of claim 19, wherein the computer program logic recorded thereon for adjusting further comprises computer program logic recorded thereon for adjusting at least one of the:
pitch;
timbre;
octave;
sharpness
scale;
rhythm;
volume;
speed;
language; and
accent.
